(19) United States
(12) Patent Application Publication
(10) Pub. No.: US 2026/0025986 A1
(43) Pub. Date: Jan. 22, 2026

(54) SELECTIVE MEMORY CELL CONTACT LINER

(71) Applicant: Micron Technology, Inc., Boise, ID (US)

(72) Inventors: Elisabeth Barr, Boise, ID (US); Jordan D. Greenlee, Boise, ID (US); Andrew L. Li, Boise, ID (US); Yi Fang Lee, Boise, ID (US); Albert P. Chan, Boise, ID (US); Silvia Borsari, Boise, ID (US); Yen Ting Lin, Taichung (TW)

(21) Appl. No.: 19/270,128

(22) Filed: Jul. 15, 2025

Related U.S. Application Data
(60) Provisional application No. 63/674,199, filed on Jul. 22, 2024.

(51) Int. Cl. H10B 12/00; H01L 21/768

(52) U.S. Cl. CPC H10B 12/485; H01L 21/76843; H01L 21/76877; H10B 12/312; H10B 12/482

(57) ABSTRACT

Methods, systems, and devices for a selective memory cell contact liner are described. A memory array may implement a protective liner within a memory cell structure including a cell contact for coupling memory storage material with an access device, a bit line associated with accessing the memory cell structure, and a bit line contact associated with activating the bit line. Forming the memory cell structure with the protective liner may include forming memory storage material, insulative material around the memory storage material, the bit line contact, the bit line, and the cavity. Then, a portion of the memory storage material may be replaced with a material associated with impeding deposition of the protective liner. The protective liner may be deposited within the cavity such that the bit line contact is covered by the protective liner but the memory storage material is not covered by the protective liner.

### CROSS REFERENCE

The present Application for Patent claims priority to U.S. Patent Application No. 63/674,199 by Barr et al., entitled “SELECTIVE MEMORY CELL CONTACT LINER,” filed Jul. 22, 2024, which is assigned to the assignee hereof, and which is expressly incorporated by reference in its entirety herein.

### TECHNICAL FIELD

The following relates to one or more systems for memory, including a selective memory cell contact liner.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports a selective memory cell contact liner in accordance with examples as disclosed herein.

FIG. 2 shows an example of an architecture that supports a selective memory cell contact liner in accordance with examples as disclosed herein.

FIGS. 3A, 3B, 3C, 3D, 3E, and 3F show examples of processing steps that support a selective memory cell contact liner in accordance with examples as disclosed herein.

FIG. 4 shows a flowchart illustrating a method or methods that support a selective memory cell contact liner in accordance with examples as disclosed herein.

### DETAILED DESCRIPTION

In some memory applications, the size of a volatile memory device (e.g., a dynamic random access memory (DRAM) device) may be reduced to decrease a footprint (e.g., area, space) of the volatile memory device or to support increased memory implementation within the same footprint, or both. Accordingly, the size of some components of the volatile memory device may be reduced to support decreasing the size of the volatile memory device. For example, an array of memory cells within a memory device may be reduced in size, which may be achieved by reducing the size of individual memory cell structures (e.g., DRAM structures) within the array. The memory cell structure may include memory storage material (e.g., chalcogenide or some other type of material), a cell contact for coupling the memory storage material with an access device (e.g., a capacitor associated with the memory cell structure), a bit line associated with accessing the memory cell structure, and a bit line contact associated with activating the bit line. In some examples, reducing the size of the memory cell structure may cause the cell contact to contact the bit line contact, thereby causing shorting at the memory cell structure. In some such examples, the shorting may be a result of manufacturing techniques for forming the memory cell structure with the reduced size.

In accordance with examples as described herein, a memory array (e.g., a volatile memory array) of a memory device may include a protective liner within memory cell structures of the memory array. The protective liner may surround a bit line and a bit line contact of a memory cell structure in a cavity associated with forming a cell contact of the memory cell structure. The protective liner may be selectively positioned such that the protective liner is not in contact with at least a portion of the memory cell storage material, such that the memory cell storage material may be in contact with the cell contact, but the protective liner may protect the bit line contact by reducing or mitigating contact between the bit line contact and the cell contact, which may reduce the likelihood of shorting in the memory cell. In some cases, forming the memory cell structure with the protective liner may include forming a memory cell structure by depositing the memory storage material between bit lines, depositing insulative material around the memory storage material, depositing conductive material to form the bit line contact, and removing a portion of the insulative material and a portion of the memory storage material to form a cavity. Then, a portion of the memory storage material may be replaced or otherwise altered with a material associated with facilitating an impeding deposition of the protective liner. The protective liner may be deposited within the cavity. The replacement or other modification of the memory storage material may not support deposition of the protective liner, such that the bit line contact may be covered by the protective liner but the memory storage material may not be covered by the protective liner (e.g., to facilitate formation of the cell contact in the cavity). Implementing the protective liner in the memory cell structure may allow the cell contact to couple with the memory storage material and an access device without shorting with the bit line contact. Thus, implementing the protective liner in the memory cell structures of the memory array may enable size reduction of the memory array without unintentional shorting otherwise caused by the size reduction.

In addition to applicability in memory systems as described herein, techniques for a selective memory cell contact liner may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by preventing shorting within memory cell structures otherwise resulting from decreasing the size of the memory cell structures, which may improve access reliability (e.g., reduce defaults) and improve user experience, among other benefits.

In addition to applicability in memory systems as described herein, techniques for a selective memory cell contact liner may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by preventing shorting within memory cell structures otherwise resulting from decreasing the size of the memory cell structures, which may result in reduced electronic waste by extending the life of electronic devices, among other benefits.

Features of the disclosure are illustrated and described in the context of systems and architectures. Features of the disclosure are further illustrated and described in the context of processing steps and flowcharts.

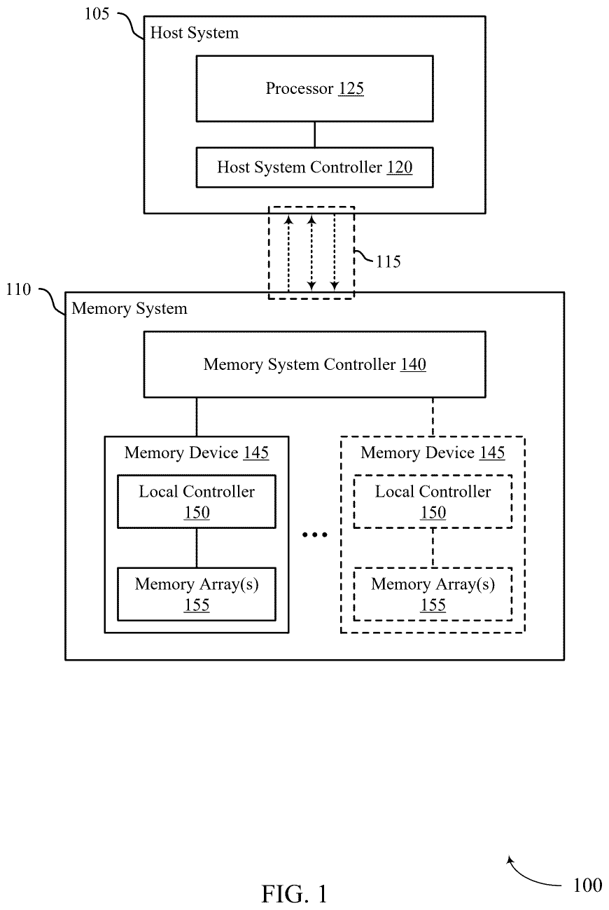

FIG. 1 illustrates an example of a system 100 that supports a selective memory cell contact liner in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In accordance with examples as described herein, the memory array 155 may include a protective liner within memory cell structures of the memory array 155. The protective liner may surround a bit line and a bit line contact of a memory cell structure in a cavity associated with forming a cell contact of the memory cell structure. The protective liner may be selectively positioned such that the protective liner is not in contact with at least a portion of the memory cell storage material, such that the memory cell storage material may be in contact with the cell contact, but the protective liner may protect the bit line contact by reducing or mitigating contact between the bit line contact and the cell contact, which may reduce the likelihood of shorting in the memory cell. In some cases, forming the memory cell structure with the protective liner may include forming a memory cell structure by depositing the memory storage material between bit lines, depositing insulative material around the memory storage material, depositing conductive material to form the bit line contact, and removing a portion of the insulative material and a portion of the memory storage material to form a cavity. Then, a portion of the memory storage material may be replaced or otherwise altered with a material associated with facilitating an impeding deposition of the protective liner. The protective liner may be deposited within the cavity. The replacement or other modification of the memory storage material may not support deposition of the protective liner, such that the bit line contact may be covered by the protective liner but the memory storage material may not be covered by the protective liner (e.g., to facilitate formation of the cell contact in the cavity). Implementing the protective liner in the memory cell structure may allow the cell contact to couple with the memory storage material and an access device without shorting with the bit line contact. Thus, implementing the protective liner in the memory cell structures of the memory array 155 may enable size reduction of the memory array 155 without unintentional shorting otherwise caused by the size reduction.

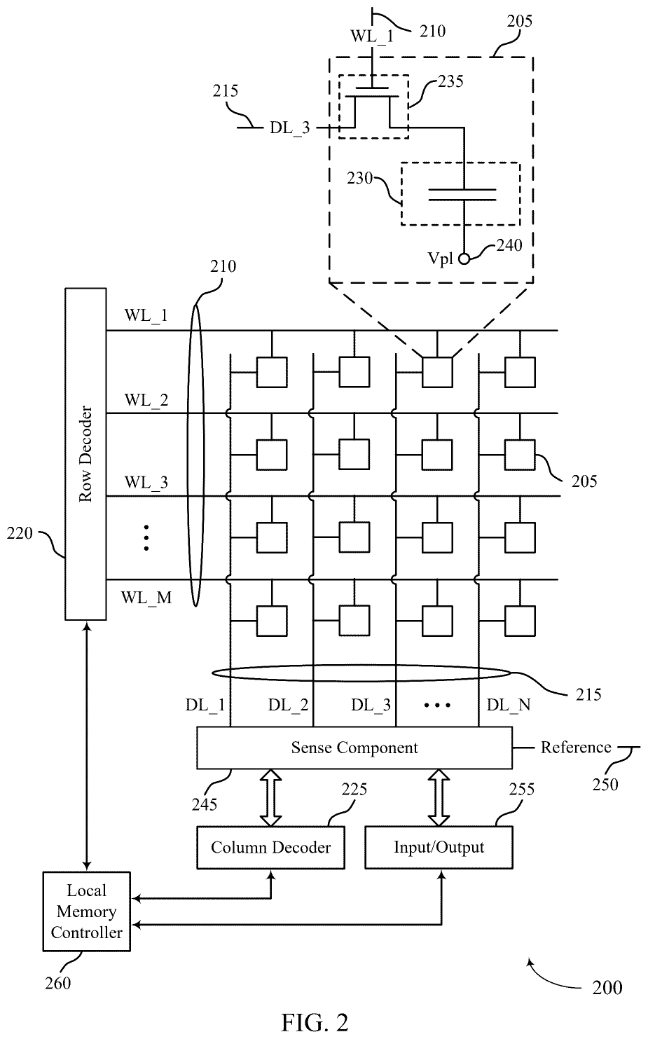

FIG. 2 illustrates an example of an architecture 200 (e.g., a memory architecture) that supports a selective memory cell contact liner in accordance with examples as disclosed herein. The architecture 200 may be implemented in a memory system 110 or one or more components thereof (e.g., memory device 145). Aspects of the architecture 200 may be referred to as or implemented in a semiconductor component, such as a memory die.

The architecture 200 includes memory cells 205 that are programmable to store information. In some examples, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). Memory cells 205 may be arranged in an array, such as in a memory array 155.

In the example of architecture 200, a memory cell 205 may include a storage component, such as capacitor 230, and a selection component 235 (e.g., a cell selection component, a transistor). A capacitor 230 may be a dielectric capacitor or a ferroelectric capacitor. A node of the capacitor 230 may be coupled with a voltage source 240, which may be a cell plate reference voltage, such as Vpl, or may be a ground voltage, such as Vss. A charge stored by a memory cell 205 (e.g., by a capacitor 230) may be representative of a programmed state. Other memory architectures that support the techniques described herein may implement different types or arrangements of storage components and associated circuitry (e.g., with or without a selection component).

The architecture 200 may include various arrangements of access lines, such as word lines 210 and digit lines 215. An access line may be a conductive line that is coupled with a memory cell 205, and may be used to perform access operations on the memory cell 205. Word lines 210 may be referred to as row lines, and digit lines 215 may be referred to as column lines or bit lines, among other nomenclature. Memory cells 205 may be positioned at intersections of access lines, and an intersection may be referred to as an address of a memory cell 205.

In some architectures, a word line 210 may be coupled with a gate of a selection component 235 of a memory cell 205, and may be operable to control (e.g., switch, modulate a conductivity of) the selection component 235. A digit line 215 may be operable to couple a memory cell 205 with a sense component 245. In some architectures, a memory cell 205 (e.g., a capacitor 230) may be coupled with a digit line 215 during portions of an access operation. For example, a word line 210 and a selection component 235 of a memory cell 205 may be operable to couple or isolate a capacitor 230 of the memory cell 205 with a digit line 215.

Operations such as reading and writing may be performed on memory cells 205 by activating (e.g., applying a voltage to) access lines such as a word line 210 or a digit line 215. Accessing the memory cells 205 may be controlled through a row decoder 220, or a column decoder 225, or a combination thereof. For example, a row decoder 220 may receive a row address (e.g., from a local memory controller 260) and activate a word line 210 based on a received row address, and a column decoder 225 may receive a column address and activate a digit line 215 based on a received column address. Selecting or deselecting a memory cell 205 may include activating or deactivating a selection component 235 using a word line 210. For example, a capacitor 230 may be isolated from a digit line 215 when the selection component 235 is deactivated, and the capacitor 230 may be coupled with the digit line 215 when the selection component 235 is activated.

A sense component 245 may be operable to detect a state (e.g., a charge) stored by a capacitor 230 of a memory cell 205 and determine a logic state of the memory cell 205 based on the stored state. A sense component 245 may include one or more sense amplifiers to amplify or otherwise convert a signal resulting from accessing the memory cell 205. The sense component 245 may compare a signal detected from the memory cell 205 with a reference 250 (e.g., a reference voltage). The detected logic state of the memory cell 205 may be provided as an output of the sense component 245 (e.g., via an input/output 255), and may indicate the detected logic state to another component of a memory system 110 that implements the architecture 200.

The local memory controller 260 may control the accessing of memory cells 205 through the various components (e.g., a row decoder 220, a column decoder 225, a sense component 245), and may be an example of or otherwise included in a local controller 150, or a memory system controller 140, or both. In some examples, one or more of a row decoder 220, a column decoder 225, and a sense component 245 may be co-located with or included in the local memory controller 260. The local memory controller 260 may be operable to receive commands or data from one or more different controllers (e.g., a host system controller 120, a memory system controller 140), translate the commands or the data into information that can be used by the architecture 200, initiate or control one or more operations of the architecture 200, and communicate data from the architecture 200 to a host (e.g., a host system 105) based on performing the one or more operations.

The local memory controller 260 may be operable to perform one or more access operations on one or more memory cells 205 of the architecture 200. Examples of an access operation may include a write operation, a read operation, a refresh operation, a precharge operation, or an activate operation, among others. In some examples, an access operation may be performed by or otherwise coordinated by the local memory controller 260 in response to one or more access commands (e.g., from a host system 105). The local memory controller 260 may be operable to perform other access operations not listed here or other operations related to the operating of the architecture 200 that are not directly related to accessing the memory cells 205.

In accordance with examples as described herein, a memory array implementing the architecture 200 may include a protective liner within memory cell structures of the memory array. The protective liner may surround a bit line and a bit line contact of a memory cell structure in a cavity associated with forming a cell contact of the memory cell structure. The protective liner may be selectively positioned such that the protective liner is not in contact with at least a portion of the memory cell storage material, such that the memory cell storage material may be in contact with the cell contact, but the protective liner may protect the bit line contact by reducing or mitigating contact between the bit line contact and the cell contact, which may reduce the likelihood of shorting in the memory cell. In some cases, forming the memory cell structure with the protective liner may include forming a memory cell structure by depositing the memory storage material between bit lines, depositing insulative material around the memory storage material, depositing conductive material to form the bit line contact, and removing a portion of the insulative material and a portion of the memory storage material to form a cavity. Then, a portion of the memory storage material may be replaced or otherwise altered with a material associated with facilitating an impeding deposition of the protective liner. The protective liner may be deposited within the cavity. The replacement or other modification of the memory storage material may not support deposition of the protective liner, such that the bit line contact may be covered by the protective liner but the memory storage material may not be covered by the protective liner (e.g., to facilitate formation of the cell contact in the cavity). Implementing the protective liner in the memory cell structure may allow the cell contact to couple with the memory storage material and an access device without shorting with the bit line contact. Thus, implementing the protective liner in the memory cell structures of the memory array may enable size reduction of the memory array without unintentional shorting otherwise caused by the size reduction.

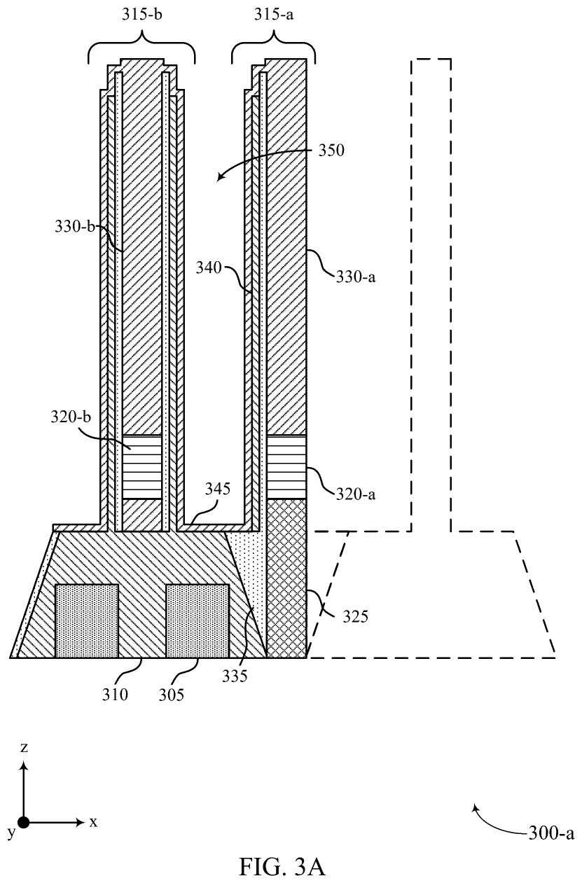

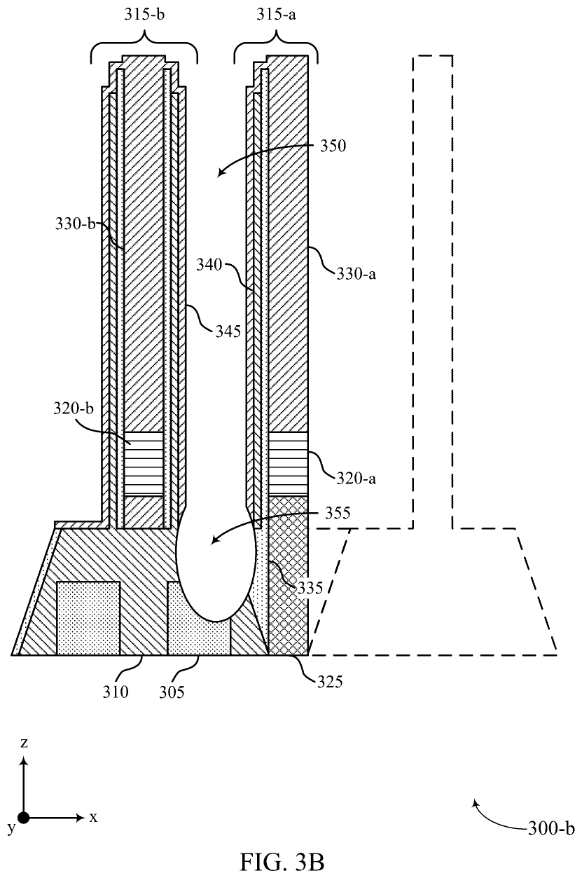

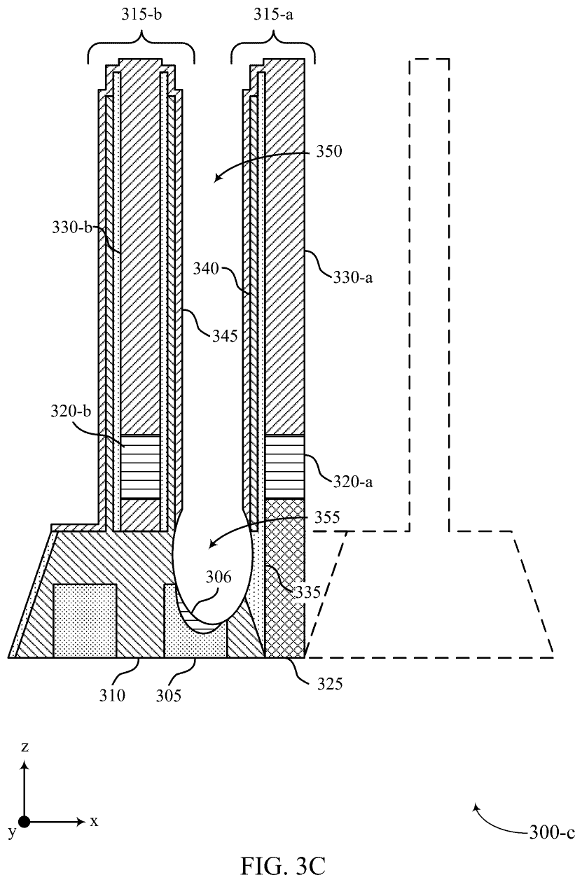

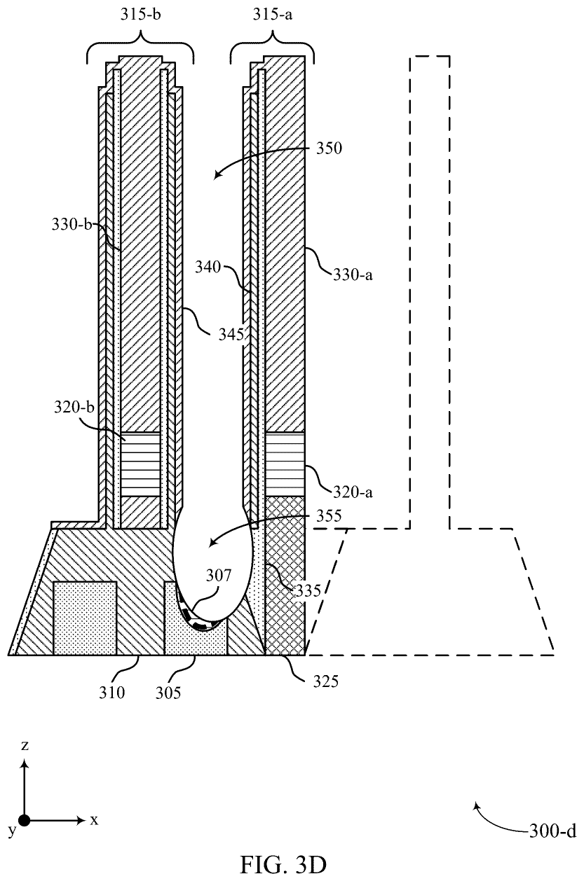

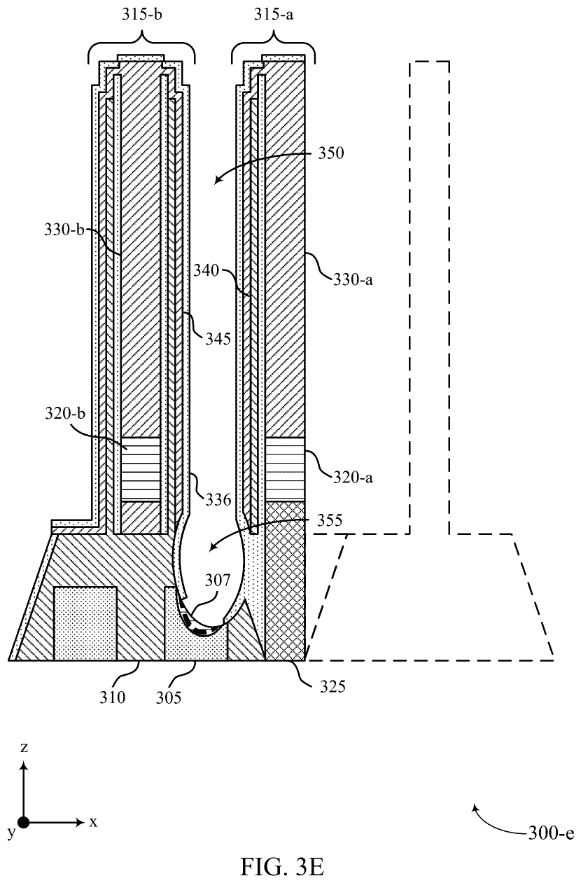

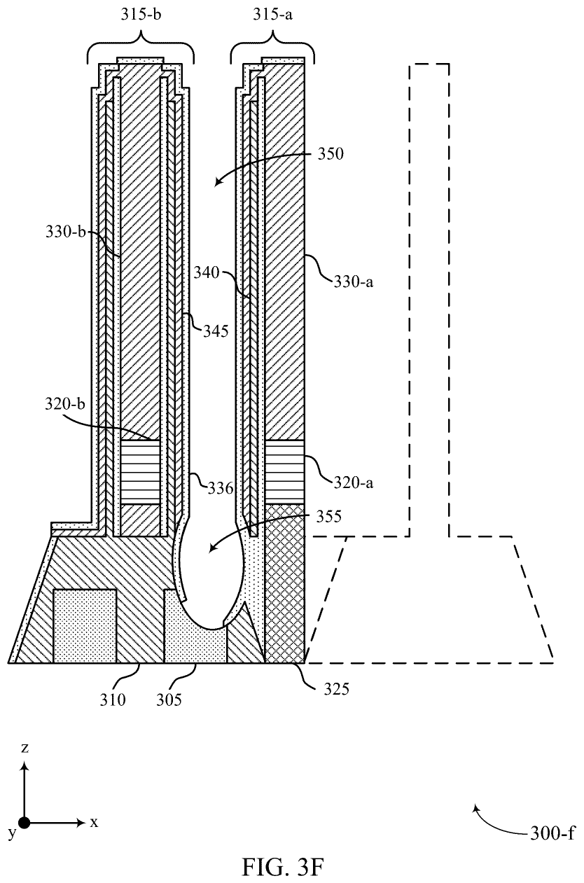

FIGS. 3A through 3F show examples of processing steps 300 that support a selective memory cell contact liner in accordance with examples as disclosed herein. FIGS. 3A through 3F show cross-sectional views of a memory cell structure. The processing steps 300 may illustrate aspects of manufacturing operations for fabricating aspects of the memory cell structure, which may be implemented in a memory array, such as a memory array 155, as described with reference to FIG. 1. Likewise, the processing steps 300 may illustrate aspects of manufacturing operations for fabricating aspects of the memory cell architecture, which may be implemented in an architecture 200, as described with reference to FIG. 2.

For illustrative purposes, aspects of the memory cell structure may be described with reference to an x-direction, a y-direction, and a z-direction of the illustrated coordinate systems. In some cases, the memory cell structure may be described relative to various cross-sectional views. For example, processing steps 300-a, 300-b, 300-c, 300-d, 300-e, and 300-f illustrate the memory cell structure from a cross-sectional view in an xz-plane, where the memory cell structure extends a distance along the y-direction into the page. Although the processing steps 300 illustrate examples of relative dimensions and quantities of various features, aspects of the memory cell structure may be implemented with other relative dimensions or quantities of such features in accordance with examples as disclosed herein. In the following description of the processing steps 300, some methods, techniques, processes, and operations may be performed in different orders or at different times. Further, some operations may be left out of the processing steps 300, or other operations may be added to the processing steps 300. The processing steps 300 may illustrate operations associated with forming the memory cell structure in which a protective liner prevents shorting between a cell contact and a bit line contact.

Operations illustrated in and described with reference to FIGS. 3A through 3F may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 3A illustrates a first processing step 300-a for forming the memory cell structure. The memory cell structure may illustrate a first instance of a memory cell structure and may be one of multiple instances of the memory cell structure formed during formation of a memory array. The dashed lines illustrated in FIG. 3A may represent another memory cell structure that is included in the memory array (e.g., an adjacent memory cell). Details of the other memory cell structure are not illustrated, for clarity, but may be understood to be similar to features of the memory cell structure illustrated in FIG. 3A. The memory cell structure may be associated with a DRAM cell structure, such that the memory cell structure may be implemented within a DRAM array, or some other type of memory array.

The memory cell structure may include a substrate (not illustrated) above which other materials and components may be formed. The memory cell structure may include memory storage material 305 disposed above the substrate. The memory storage material 305 may be deposited on the substrate in a rectangular shape and may extend in the x-direction and the z-direction as shown, and may extend some distance in the 7-direction (e.g., into and out of the page). The insulative material 310 may surround the memory storage material 305. The insulative material 310 may be deposited above and around the memory storage material 305 and may form a trapezoidal shape, in some examples in the z-direction and the x-direction, as shown. The insulative material 310 may extend some distance in the y-direction (e.g., into and out of the page).

The memory storage material 305 may be configured to store data within the memory cell structure. In some cases, the memory storage material 305 may be associated with an active region and the insulative material 310 may be associated with an inactive region of the memory cell structure. In some such cases, the memory storage material 305 may be an active silicon material (e.g., configured to store data) and the insulative material 310 may be an inactive silicon material. For example, the memory storage material 305 may be silicon (e.g., or another charge trapping material) and the insulative material 310 may be silicon oxide material, or a silicon nitride material, or another dielectric material. In some cases, the memory storage material 305 may otherwise be referenced as a memory cell, such as a DRAM cell.

The memory cell structure may include bit line structures 315 (e.g., bit line structure 315-a, bit line structure 315-b) including bit lines 320 (e.g., bit line 320-a, bit line 320-b) coupled with bit line contacts 325 above the bit lines 320 (e.g., along the z-direction). The bit lines 320 may extend along the y-direction (e.g., into the page, out of the page) in a rectangular shape and may be configured to access the memory cell of the memory cell structure. For example, the bit lines 320 may include conductive material configured to provide a voltage to the memory storage material 305 to access (e.g., read, write) data stored by the memory storage material 305. In some cases, the bit line contacts 325 may include conductive material in a rectangular shape configured to activate the bit lines 320 based on providing a voltage to the bit lines 320. In some cases, the bit line contacts 325 may be positioned within the memory cell structure such that each bit line contact 325 is disposed below and coupled with an alternating bit line 320. For example, in FIGS. 3A through 3F, the bit line contact 325 is coupled with bit line 320-a, but bit line 320-b is not coupled with a bit line contact 325. The bit line 320 may be associated with electrically isolating structures 330 (e.g., electrically isolating structure 330-a, electrically isolating structure 330-b) positioned above the bit lines 320 and formed in a rectangular shape. For example, the electrically isolating structure 330-a may be positioned above the bit line 320-a and the electrically isolating structure 330-b may be positioned above the bit line 320-b. In some implementations, the electrically isolating structures 330 may be configured to electrically isolate the bit lines 320 from other components of the memory cell structure based on a material of the electrically isolating structures 330. For example, the electrically isolating structures 330 may include a dielectric material, such as a silicon nitride material.

The memory cell structure may include liner materials configured to protect components of the bit line structures 315. For example, the bit line structure 315-a may include a liner material 335 contacting the bit line contact 325, the bit line 320-a, and the electrically isolating structure 330-a. That is, the liner material 335 may extend along the z-direction adjacent to (e.g., in the x-direction) the bit line contact 325, the bit line 320-a, and the electrically isolating structure 330-a. In other examples, the bit line structure 315-b may include the liner material 335 contacting the bit line 320-b and the electrically isolating structure 330-b. In some examples, the liner material 335 may be a silicon oxycarbide material, or another protective material. The bit line structures 315 may also include an insulating liner 340 contacting the liner material 335, such that the insulating liner 340 may extend along the liner material 335 in the z-direction adjacent to both the liner material 335 and an electrically isolating liner 345. In some cases, the liner material 335 may be a dielectric material, such as a silicon oxide or silicon nitride material. The memory cell structure may also include an electrically isolating liner 345 contacting the insulating liner 340 and the insulative material 310. That is, the electrically isolating liner 345 may be formed within a cavity 350 between the bit line structures 315. In some examples, the electrically isolating liner 345 may be connected with the electrically isolating structures 330 and may be a same material as the electrically isolating structures 330, such that the electrically isolating liner 345 may be a silicon nitride material.

In some cases, forming the memory cell structure may include performing a series of processing steps not illustrated in FIGS. 3A through 3F. For example, FIG. 3A illustrates the memory cell structure after forming the substrate, the memory storage material 305, the insulative material 310, and the bit line structures 315 (e.g., and the components thereof).

FIG. 3B illustrates a second processing step 300-b for forming a cavity 355 within the memory cell structure. Forming the cavity 355 may include removing portions of the memory cell structure. For example, forming the cavity 355 may include removing a portion of the memory storage material 305, a portion of the insulative material 310, and a portion of the liner material 335. In some cases, forming the cavity 355 may include performing a punch etch operation, which may be a dry etch operation associated with removing material. In some examples, the cavity 355 may be formed between the bit line structures 315, such that the cavity 355 (e.g., a second cavity) may be formed within the cavity 350 (e.g., a first cavity). In some such examples, the cavity 355 may be an extension of the cavity 350. In some implementations, the cavity 350 may be used as an access point for manufacturing operations associated with forming the cavity 355. Although not illustrated in FIG. 3B, in some examples, forming the cavity 355 may include removing the portion of the liner material 335 such that the cavity 355 exposes the bit line contact 325. Additionally, or alternatively, at least some of the liner material 335 may remain along a sidewall of the bit line contact 325, such that the bit line contact 325 is not exposed via the cavity. If the liner material 335 is damaged and/or removed, it may create an electrical connection between the bit line contact 325 and whatever material is inserted into the cavity 355. Techniques are described for isolating the bit line contact 325 whatever material is inserted into the cavity 355 and maintaining other electrical connections that are desired.

In some cases, the cavity 355 may be formed such that the cavity 355 has a curved shape. For example, the cavity 355 may be a portion of an oval or other curved shape and the sidewalls of the cavity 355 may curve according to the size of the oval. In some examples, the cavity 355 and the cavity 350 may form the shape of a cotton swab or a lollipop, for example. In other cases, the cavity 355 may be a rectangular shape, such that the sidewalls of the cavity 355 may be straight. In some cases, the cavity 355 may be triangular, such that the sidewalls of the cavity 355 may be straight and positioned at an angle relative to the substrate. In other cases, the cavity 355 may be an amorphous shape, in which some sidewalls of the cavity 355 may be curved or straight or both.

FIG. 3C illustrates a third processing step 300-c for replacing a portion of the memory storage material 305 with a metal material 306. For example, the portion of the memory storage material 305 may be exposed to the cavity 355 and may extend at least partially into the memory storage material 305. In some cases, the portion of the memory storage material 305 may be a curved portion, such that the portion may be ovular from an exposed surface of the memory storage material 305 (e.g., via the cavity 355). In some cases, replacing the portion of the memory storage material 305 with the metal material 306 may include converting the portion of the memory storage material 305 to the metal material 306. For example, converting the portion of the memory storage material 305 may include performing a wisteria conversion to convert the silicon material of the memory storage material 305 to the metal material 306.

In some implementations, performing the wisteria conversion may include exposing the memory storage material 305 to a gas or plasma, such as tungsten fluoride. In other cases, replacing the portion of the memory storage material 305 may include removing the portion of the memory storage material 305 and depositing the metal material 306 in the space otherwise associated with the removed portion. For example, the portion of the memory storage material 305 may be etched and the metal material 306 may fill the etched portion. In some cases, the metal material 306 may be a tungsten material. In other cases, the metal material 306 may be a molybdenum material, a cobalt material, a tungsten nitride material, or a tungsten silicide material. In some examples, the metal material 306 may be the same material as the bit lines 320, or a different material.

FIG. 3D illustrates a fourth processing step 300-d for oxidizing the metal material 306. Oxidizing the metal material 306 may include exposing the metal material 306 to a gas or plasma, such as oxygen or sulfur. In some cases, oxidizing the metal material 306 may include performing an ozone operation on the metal material 306 or a white oxidation operation on the metal material 306. Oxidizing the metal material 306 may form a metal oxide material 307 in the etched portion of the memory storage material 305. In some cases, the metal oxide material 307 may impede (e.g., resist, prevent) deposition operations, such that some materials may not form on the metal oxide material 307.

FIG. 3E illustrates a fifth processing step 300-e for forming a protective liner 336. In some cases, the protective liner 336 may be formed within the cavity 355 and the cavity 350, as well as around the bit line structures 315. The protective liner 336 may be deposited on sidewalls of the cavity 355 and the cavity 350, such that the protective liner 336 may be formed on the sidewalls of the electrically isolating liner 345, the insulative material 310, and the liner material 335. Additionally, the protective liner 336 may be deposited on sidewalls of and on top of the electrically isolating structures 330. In some cases, the protective liner 336 may be a silicon oxycarbide material, or another protective material. In some examples, the protective liner 336 may be a same material as the liner material 335.

In some cases, the protective liner 336 may be formed such that the protective liner 336 maintains a consistent thickness along the sidewalls of the cavity 355 and the cavity 350. For example, the protective liner 336 may be deposited such that the thickness of the protective liner 336 satisfies a threshold at each point along the sidewalls of the cavity 355 and the cavity 350. In some cases, the threshold may be a range, such that satisfying the threshold may be understood as the protective liner 336 having a minimum thickness equal to or greater than the lowest value of the range and a maximum thickness equal to or less than a greatest value of the range. In other cases, the threshold may be a single value, such that satisfying the threshold may be understood as the protective liner 336 having a thickness equal to or greater than the threshold value. In some examples, the protective liner 336 may not be present at all above the metal material 306, but the protective liner 336 may maintain the threshold thickness elsewhere, including in the regions directly adjacent to the metal material 306.

For example, the metal material 306 may impede deposition of the protective liner 336, such that the protective liner 336 may not form on the metal material 306. In other cases, the metal oxide material 307 may impede deposition of the protective liner 336 based on the oxidization of the metal material 306, such that the protective liner 336 may not form on the metal oxide material 307 as a result of the oxidization. In some examples, the protective liner 336 may electrically isolate the bit line contact 325 from other components of the memory cell structure. For example, the protective liner 336 may be formed on a sidewall of the bit line contact 325 or may increase a thickness of the liner material 335 previously positioned along the sidewall of the bit line contact 325. The protective liner 336 may protect the bit line contact 325 from processing steps and prevent coupling between the memory storage material 305 and the bit line contact 325. Using the metal material 306 and/or metal oxide material 307 to impede deposition of the protective liner 336 may provide for the protective liner 336 to maintain a relatively constant thickness and rigidity even in the areas near the metal material 306. If, for example, the protective liner 336 was deposited over the metal material 306 and subsequently etched, the thickness and quality of the protective liner 336 may be degraded near the metal material 306 based on the etch process.

FIG. 3F illustrates a sixth processing step 300-f for removing the metal material 306. In some cases, the metal material 306 may be removed based on forming the protective liner 336. In some examples, removing the metal material 306 may include removing the metal oxide material 307. Removing the metal material 306 may result in exposure of the memory storage material 305 to the cavity 355. In some implementations, the metal material 306 may be removed via an exhumation process.

After removing the metal material 306, the sixth processing step 300-f may include forming a cell contact. The cell contact may be formed within the cavity 350 and the cavity 355, such that the cell contact may contact the protective liner 336 and the memory storage material 305. In some cases, the cell contact may be a conductive material, such as a metal material or a polysilicon material (e.g., to reduce magnetic field interactions). The cell contact may be formed based on depositing the conductive material in the cavity 350 and the cavity 355. In some cases, after forming the cell contact, an access device may be formed above the memory cell structure. The access device may be a capacitor associated with the memory storage material 305, and the cell contact may couple the memory storage material 305 with the access device.

Implementing the metal material 306 (e.g., or the metal oxide material 307) may enable the protective liner 336 to be formed and protect against shorting between other materials in the memory cell structure, such as between the cell contact and the bit line contact 325, without protecting the memory storage material 305 from contacting the cell contact, which may otherwise disable functionality for accessing the memory cell. Likewise, implementing the protective liner 336 may preventing shorting from occurring between the cell contact and the bit line contact 325, thereby providing greater reliability for accessing the memory cell. Thus, applying the processing steps 300 may be associated with improved functionality and reliability for operating the memory cell, as well as manufacturing selectivity for supporting decreased memory cell structure size.

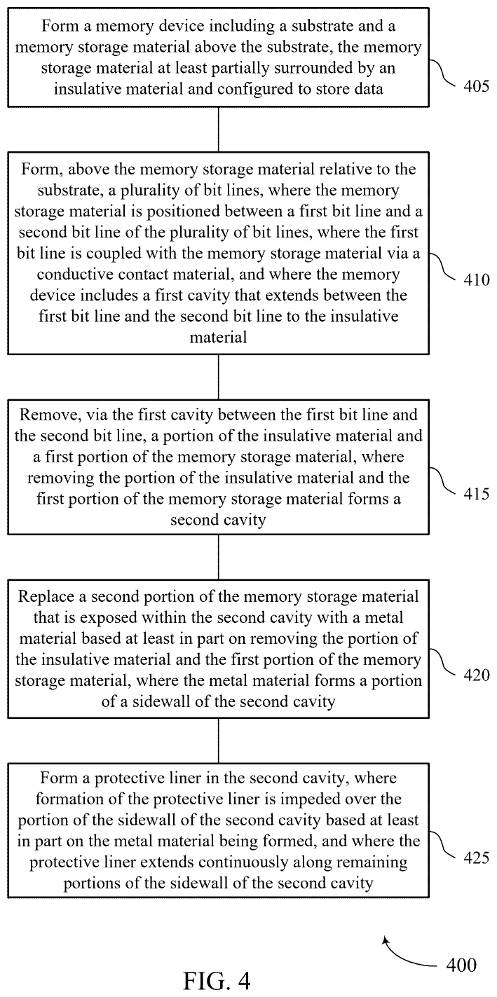

FIG. 4 shows a flowchart illustrating a method or methods 400 that supports a selective memory cell contact liner in accordance with examples as disclosed herein. The operations of method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include forming a memory device including a substrate and a memory storage material above the substrate, the memory storage material at least partially surrounded by an insulative material and configured to store data.

At 410, the method may include forming, above the memory storage material relative to the substrate, a plurality of bit lines, where the memory storage material is positioned between a first bit line and a second bit line of the plurality of bit lines, where the first bit line is coupled with the memory storage material via a conductive contact material, and where the memory device includes a first cavity that extends between the first bit line and the second bit line to the insulative material.

At 415, the method may include removing, via the first cavity between the first bit line and the second bit line, a portion of the insulative material and a first portion of the memory storage material, where removing the portion of the insulative material and the first portion of the memory storage material forms a second cavity.

At 420, the method may include replacing a second portion of the memory storage material that is exposed within the second cavity with a metal material based at least in part on removing the portion of the insulative material and the first portion of the memory storage material, where the metal material forms a portion of a sidewall of the second cavity.

At 425, the method may include forming a protective liner in the second cavity, where formation of the protective liner is impeded over the portion of the sidewall of the second cavity based at least in part on the metal material being formed, and where the protective liner extends continuously along remaining portions of the sidewall of the second cavity.

In some examples, an apparatus as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a memory device including a substrate and a memory storage material above the substrate, the memory storage material at least partially surrounded by an insulative material and configured to store data; forming, above the memory storage material relative to the substrate, a plurality of bit lines, where the memory storage material is positioned between a first bit line and a second bit line of the plurality of bit lines, where the first bit line is coupled with the memory storage material via a conductive contact material, and where the memory device includes a first cavity that extends between the first bit line and the second bit line to the insulative material; removing, via the first cavity between the first bit line and the second bit line, a portion of the insulative material and a first portion of the memory storage material, where removing the portion of the insulative material and the first portion of the memory storage material forms a second cavity; replacing a second portion of the memory storage material that is exposed within the second cavity with a metal material based at least in part on removing the portion of the insulative material and the first portion of the memory storage material, where the metal material forms a portion of a sidewall of the second cavity; and forming a protective liner in the second cavity, where formation of the protective liner is impeded over the portion of the sidewall of the second cavity based at least in part on the metal material being formed, and where the protective liner extends continuously along remaining portions of the sidewall of the second cavity.

Aspect 2: The method or apparatus of aspect 1, further including operations, features, circuitry, logic, means, or instructions, or any combination thereof for removing the metal material based at least in part on depositing the protective liner in the second cavity.

Aspect 3: The method or apparatus of any of aspects 1 through 2, further including operations, features, circuitry, logic, means, or instructions, or any combination thereof for oxidizing the metal material based at least in part on replacing the second portion of the memory storage material that is exposed within the second cavity with the metal material and where the formation of the protective liner is impeded over the portion of the sidewall of the second cavity based at least in part on oxidizing the metal material.

Aspect 4: The method or apparatus of aspect 3, where oxidizing the metal material includes operations, features, circuitry, logic, means, or instructions, or any combination thereof for exposing the metal material to an oxygen gas plasma or a sulfur gas plasma.

Aspect 5: The method or apparatus of any of aspects 1 through 4, where replacing the second portion of the memory storage material that is exposed within the second cavity with the metal material includes operations, features, circuitry, logic, means, or instructions, or any combination thereof for converting the second portion of the memory storage material to the metal material.

Aspect 6: The method or apparatus of any of aspects 1 through 5, where replacing the second portion of the memory storage material that is exposed within the second cavity with the metal material includes operations, features, circuitry, logic, means, or instructions, or any combination thereof for removing the second portion of the memory storage material and depositing the metal material in a third cavity formed by removing the second portion of the memory storage material.

Aspect 7: The method or apparatus of any of aspects 1 through 6, where depositing the protective liner in the second cavity includes operations, features, circuitry, logic, means, or instructions, or any combination thereof for depositing the protective liner in a plurality of second cavities between adjacent bit lines of the plurality of bit lines.

Aspect 8: The method or apparatus of any of aspects 1 through 7, further including operations, features, circuitry, logic, means, or instructions, or any combination thereof for depositing a conductive material in the second cavity based at least in part on depositing the protective liner in the second cavity.

Aspect 9: The method or apparatus of aspect 8, where the conductive material extends through the first cavity and couples with the memory storage material and an access device associated with the memory storage material.

Aspect 10: The method or apparatus of any of aspects 1 through 9, where the memory device further includes operations, features, circuitry, logic, means, or instructions, or any combination thereof for a plurality of electrically isolating structures above the plurality of bit lines, where the plurality of electrically isolating structures each include a silicon nitride material.

Aspect 11: The method or apparatus of any of aspects 1 through 10, where the protective liner includes silicon oxycarbide material.

Aspect 12: The method or apparatus of any of aspects 1 through 11, where the metal material includes tungsten material, a molybdenum material, a cobalt material, a tungsten nitride material, or a tungsten silicide material.

Aspect 13: The method or apparatus of any of aspects 1 through 12, where the insulative material includes a silicon oxide material or a silicon nitride material.

Aspect 14: The method or apparatus of any of aspects 1 through 13, where removing the portion of the insulative material and the first portion of the memory storage material expands a size of the first cavity and the second cavity includes an extension of the first cavity based at least in part on the removal.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: A memory device, including: a substrate; a plurality of bit lines that extend in a first layer; a plurality of bit line contacts coupled with the plurality of bit lines, respectively; and a memory cell between two adjacent bit lines of the plurality of bit lines, where the memory cell includes: an active region operable to be coupled to a first bit line of the two adjacent bit lines via a first bit line contact of the plurality of bit line contacts, the active region positioned in a second layer that is closer to the substrate than the first layer; a capacitor positioned in a third layer, the third layer positioned farther from the substrate than the first layer and the second layer; a contact coupled with the active region in the second layer and coupled with the capacitor in the third layer, where the contact includes a conductive material positioned between the two adjacent bit lines in the first layer; and a protective liner that extends along sidewalls of the contact, where the protective liner is positioned between the conductive material and the first bit line contact, and where the protective liner includes an opening through which the active region couples with the contact.

Aspect 16: The memory device of aspect 15, further including: a memory cell contact coupled with the active region based at least in part on the protective liner including the opening through which the active region couples with the contact.

Aspect 17: The memory device of any of aspects 15 through 16, where the conductive material includes at least two curved sidewalls in the second layer of the memory device that are in contact with the active region, and the protective liner extends along the at least two curved sidewalls in the second layer, the protective liner including a gap for a connection between the conductive material and the active region.

Aspect 18: The memory device of any of aspects 15 through 17, where the protective liner includes a thickness satisfying a threshold thickness along the sidewalls of the contact in the second layer.

Aspect 19: The memory device of any of aspects 15 through 18, where the protective liner includes a silicon oxycarbide material.

Aspect 20: The memory device of any of aspects 15 through 19, further including: a plurality of electrically isolating structures above the plurality of bit lines.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a substrate;
a plurality of bit lines that extend in a first direction in a first layer;
a plurality of bit line contacts coupled with the plurality of bit lines, respectively; and
a memory cell between two adjacent bit lines of the plurality of bit lines, wherein the memory cell comprises:
an active region operable to be coupled to a first bit line of the two adjacent bit lines via a first bit line contact of the plurality of bit line contacts, the active region positioned in a second layer that is closer to the substrate than the first layer;
a capacitor positioned in a third layer, the third layer positioned farther from the substrate than the first layer and the second layer;
a contact coupled with the active region in the second layer and coupled with the capacitor in the third layer, wherein the contact comprises a conductive material positioned between the two adjacent bit lines in the first layer; and
a protective liner that extends along sidewalls of the contact, wherein the protective liner is positioned between the conductive material and the first bit line contact, and wherein the protective liner comprises an opening through which the active region couples with the contact.

2. The memory device of claim 1, further comprising:
a memory cell contact coupled with the active region based at least in part on the protective liner comprising the opening through which the active region couples with the contact.

3. The memory device of claim 1, wherein:
the conductive material comprises at least two curved sidewalls in the second layer of the memory device that are in contact with the active region, and
the protective liner extends along the at least two curved sidewalls in the second layer, the protective liner comprising a gap for a connection between the conductive material and the active region.

4. The memory device of claim 1, wherein the protective liner comprises a thickness satisfying a threshold thickness along the sidewalls of the contact in the second layer.

5. The memory device of claim 1, wherein the protective liner comprises a silicon oxycarbide material.

6. The memory device of claim 1, further comprising:
a plurality of electrically isolating structures above the plurality of bit lines.

7. A method, comprising:
forming a memory device comprising a substrate and a memory storage material above the substrate, the memory storage material at least partially surrounded by an insulative material and configured to store data;
forming, above the memory storage material relative to the substrate, a plurality of bit lines, wherein the memory storage material is positioned between a first bit line and a second bit line of the plurality of bit lines, wherein the first bit line is coupled with the memory storage material via a conductive contact material, and wherein the memory device comprises a first cavity that extends between the first bit line and the second bit line to the insulative material;
removing, via the first cavity between the first bit line and the second bit line, a portion of the insulative material and a first portion of the memory storage material, wherein removing the portion of the insulative material and the first portion of the memory storage material forms a second cavity;
replacing a second portion of the memory storage material that is exposed within the second cavity with a metal material based at least in part on removing the portion of the insulative material and the first portion of the memory storage material, wherein the metal material forms a portion of a sidewall of the second cavity; and
forming a protective liner in the second cavity, wherein formation of the protective liner is impeded over the portion of the sidewall of the second cavity based at least in part on the metal material being formed, and wherein the protective liner extends continuously along remaining portions of the sidewall of the second cavity.

8. The method of claim 7, further comprising:
removing the metal material based at least in part on depositing the protective liner in the second cavity.

9. The method of claim 7, further comprising:
oxidizing the metal material based at least in part on replacing the second portion of the memory storage material that is exposed within the second cavity with the metal material,
wherein the formation of the protective liner is impeded over the portion of the sidewall of the second cavity based at least in part on oxidizing the metal material.

10. The method of claim 9, wherein oxidizing the metal material comprises:
exposing the metal material to an oxygen gas plasma or a sulfur gas plasma.

11. The method of claim 7, wherein replacing the second portion of the memory storage material that is exposed within the second cavity with the metal material comprises:
converting the second portion of the memory storage material to the metal material.

12. The method of claim 7, wherein replacing the second portion of the memory storage material that is exposed within the second cavity with the metal material comprises:
removing the second portion of the memory storage material; and
depositing the metal material in a third cavity formed by removing the second portion of the memory storage material.

13. The method of claim 7, wherein depositing the protective liner in the second cavity comprises:
depositing the protective liner in a plurality of second cavities between adjacent bit lines of the plurality of bit lines.

14. The method of claim 7, further comprising:
depositing a conductive material in the second cavity based at least in part on depositing the protective liner in the second cavity.

15. The method of claim 14, wherein the conductive material extends through the first cavity and couples with the memory storage material and an access device associated with the memory storage material.

16. The method of claim 7, wherein the memory device further comprises:
a plurality of electrically isolating structures above the plurality of bit lines, wherein the plurality of electrically isolating structures each comprise a silicon nitride material.

17. The method of claim 7, wherein the protective liner comprises silicon oxycarbide material.

18. The method of claim 7, wherein the metal material comprises tungsten material, a molybdenum material, a cobalt material, a tungsten nitride material, or a tungsten silicide material.

19. The method of claim 7, wherein the insulative material comprises a silicon oxide material or a silicon nitride material.

20. The method of claim 7, wherein:
removing the portion of the insulative material and the first portion of the memory storage material expands a size of the first cavity, and
the second cavity comprises an extension of the first cavity based at least in part on the removal.
